(19) United States
(12) Patent Application Publication
(10) Pub. No.: US 2026/0165040 A1
(43) Pub. Date: Jun. 11, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yen-Liang LIN, Hsinchu (TW); Hai-Dang TRINH, Hsinchu (TW)

(21) Appl. No.: 18/970,672

(22) Filed: Dec. 5, 2024

(51) Int. Cl. H10N 70/00; H10B 63/00; H10N 70/20

(52) U.S. Cl. CPC H10N 70/841; H10B 63/00; H10N 70/011; H10N 70/24; H10N 70/8265

(57) ABSTRACT

A memory device includes a bottom electrode that includes a high work function material. The high work function material enables the work function of the bottom electrode to be tuned such that current leakage in the memory device is reduced in comparison to a memory device without the high work function material. As a result of the reduced current leakage, bias of an applied bitline voltage to set a memory device to a low resistance state is reduced or prevented, and the applied bitline voltage may correspond to a required set voltage, such that fewer voltage pulses will be required to achieve the low resistance state than when a low work function material is used for the bottom electrode. The reduced number of pulses needed to achieve the low resistance state increases memory device speed and increases overall device reliability.

### BACKGROUND

A semiconductor device may include a non-volatile memory, which is able to store data in the absence of power. Non-volatile memory technologies include magneto-resistive random-access memory (MRAM), phase change random access memory (PC-RAM), and resistive random access memory (RRAM), among other examples. These non-volatile memory technologies are compatible with complementary metal-oxide-semiconductor (CMOS) logic fabrication processes, which enables logic and memory circuitry to be integrated onto the same semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example semiconductor device described herein.

FIGS. 2A-2E are diagrams of an example implementation of forming a semiconductor device described herein.

FIGS. 3A-3D are diagrams illustrating example implementations of operation of a memory device described herein.

FIGS. 4A-4J are diagrams of an example implementation of forming a memory device described herein.

FIG. 5 is a circuit diagram of an array of memory cells, each including a memory device described herein.

FIG. 6 is a flowchart of an example process associated with forming a semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A resistive random access memory (RRAM) device may include a resistive memory layer between a bottom electrode and a top electrode. The RRAM device may be selectively set to a low resistance state (LRS) or reset to a high resistance state (HRS). To set the RRAM device to the LRS, a set operation may be performed in which a set voltage may be applied from the top electrode to the bottom electrode across the resistive memory layer. The set voltage causes oxygen atoms in the resistive memory layer to be captured in the top electrode, resulting in formation of oxygen vacancies in the resistive memory layer. An electric field from the set voltage causes the oxygen vacancies to migrate toward the bottom electrode and to form a conductive filament (CF) at the bottom of the resistive memory layer. Forming the conductive filament transitions the resistive memory layer (and thus, the RRAM device) to the LRS.

To reset the RRAM device, a reset operation may be performed in which a reset voltage may be applied from the top electrode to the bottom electrode. The reset voltage reverses the process by which the conductive filament is formed such that the oxygen atoms in the top electrode combine with the oxygen vacancies in the conductive filament in the resistive memory layer. The oxygen recombination of the oxygen atoms with the oxygen vacancies transitions the resistive memory layer (and thus, the RRAM device) to the HRS.

Various techniques may be used to increase the operating efficiency of an RRAM device. One technique includes using a lower set voltage and/or a lower reset voltage for switching the RRAM device between the LRS and the HRS. A lower set voltage and/or a lower reset voltage may reduce the power consumption of the RRAM device, which may increase the operating efficiency of an RRAM device. However, a lower set voltage may result in an increase in current leakage through the resistive memory layer of the RRAM device. For example, a lower set voltage may necessitate the use of a greater quantity of set voltage pulses to set the RRAM device to the LRS than when higher set voltages are used. The greater quantity of set voltage pulses can result in the formation of a dispersed conductive filament that has a high quantity of current leakage paths, leading to increased current leakage. Moreover, the higher current leakage can result in significant drops in bitline voltage for a memory cell. As a result, an applied voltage to set an RRAM device to the LRS may be less than the required set voltage, thereby further increasing the quantity of voltage pulses needed to achieve the LRS. These additional pulses reduce memory device speed and reduce overall device reliability.

In some implementations described herein, an RRAM device includes a bottom electrode that includes a high work function material. The high work function material enables the work function of the bottom electrode to be tuned such that current leakage in the RRAM device is reduced in comparison to an RRAM device without the high work function material. For example, the high work function material provides a high electron barrier height at the interface between the bottom electrode and the resistive memory layer of the RRAM device, which more effectively resists current leakage through electron tunnelling than a lower work function material. As a result of the reduced current leakage, bias of an applied bitline voltage to set a memory device to a low resistance state is reduced or prevented, and an applied bitline voltage to set an RRAM device to the LRS may correspond to the required set voltage, such that fewer voltage pulses are required to achieve the LRS than when a low work function material is used for the bottom electrode. The reduced number of pulses needed to achieve the LRS increases memory device speed and increases overall device reliability.

The high work function material may be a metal compound material, such as a metal oxide. In addition to having a high work function, the metal compound material may have an increased tendency to acquire electrons (higher redox potential) than other materials, which may facilitate conductive filament formation since the conductive filament is formed when oxygen vacancies migrate toward the bottom electrode. Additionally, the high work function material of the bottom electrode enables the conductive filament to be formed using fewer oxygen vacancies than without the high work function material, which reduces the amount of electric field needed to transition the resistive memory layer (and thus, the RRAM device) to the LRS. Accordingly, the high work function material of the bottom electrode described herein facilitates conductive filament formation to reach the LRS during a set operation of the RRAM device.

Additionally and/or alternatively, the high work function material of the bottom electrode described herein may include lower cost materials and be more efficient to etch relative to other types of bottom electrode materials, which may provide a larger etch process parameter window than some other materials, and reduce the manufacturing cost for forming the RRAM device.

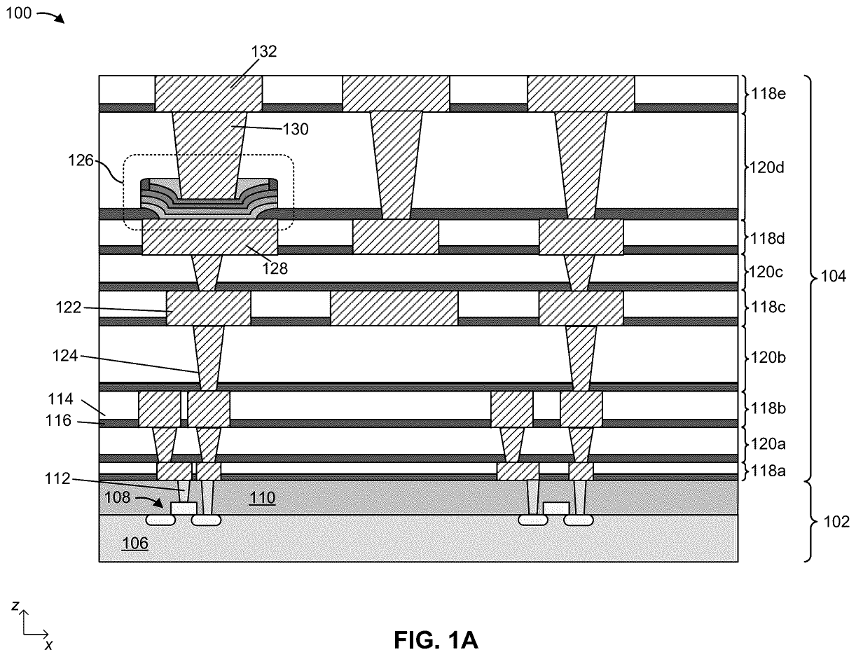

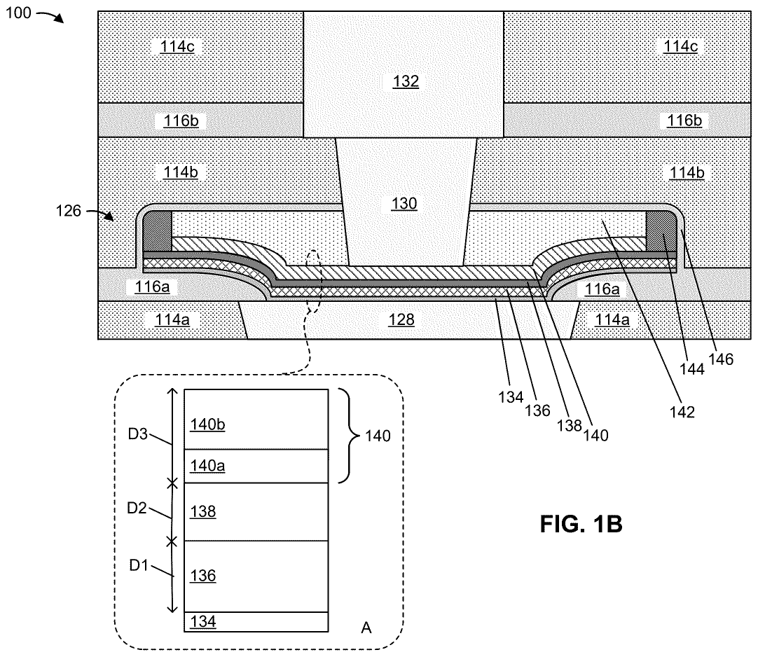

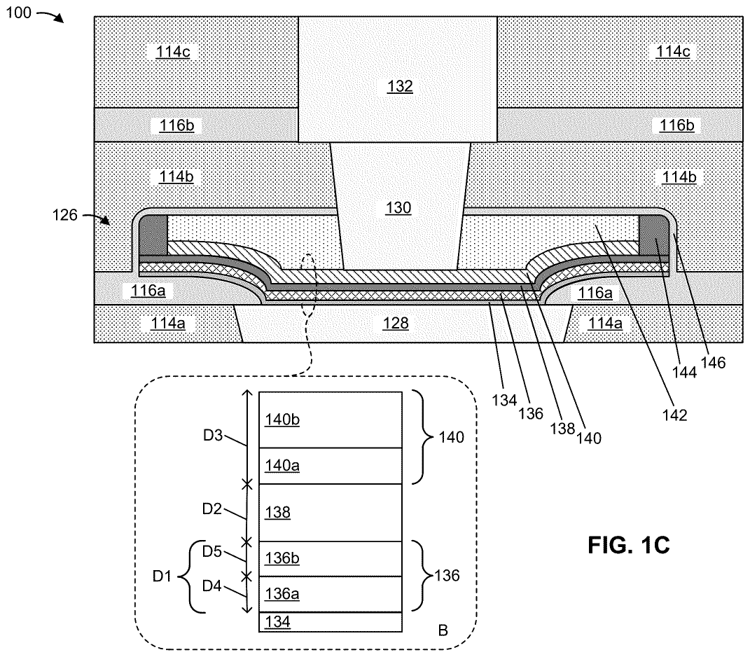

FIGS. 1A-1C are diagrams of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1A illustrates a cross-section view of the semiconductor device 100. As shown in FIG. 1A, the semiconductor device 100 may include a device layer 102 and an interconnect layer 104 arranged in a z-direction in the semiconductor device 100 with respect to the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second

interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or

protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α—CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC). Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118e that are vertically arranged and alternate with a plurality of layers 120a-120d in the z-direction (e.g., vertically alternate). The layers 118a-118e each include a layer of metallization structures 122, and the layers 120a-120d each include a layer of interconnect structures 124.

The layers 118a-118e of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO” layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1A, a memory device 126 is included in the interconnect layer 104 of the semiconductor device 100. The memory device 126 may extend through and/or may be included in one or more dielectric layers in the interconnect layer 104, such as one or more ILD layers 114 and/or one or more ESLs 116. In some implementations, an integrated circuit device 108 is electrically coupled to a memory device 126 to form a memory cell (e.g., a resistive random access memory (RRAM) cell or another type of resistance-based memory cell) in the semiconductor device 100. In some implementations, a memory device 126 is a non-volatile memory device configured to store data in the absence of power. In some implementations, a memory device 126 is configured to perform another function in the semiconductor device 100.

The memory device 126 may be electrically coupled and/or physically coupled to a bottom contact 128 at a bottom of the memory device 126, to a via 130, and to a top contact 132

at a top of the memory device 126. Alternatively, the memory device 126 may be electrically coupled and/or physically coupled to a plurality of top contacts at the top of the memory device 126. The bottom contact 128, the via 130 and the top contact 132 may each include one or more conductive structures in the interconnect layer 104, such as one or more metallization structures 122 and/or one or more interconnect structures 124, among other examples.

FIGS. 1B and 1C are diagrams of a portion of the semiconductor device 100 including the memory device 126. As shown in FIGS. 1B and 1C, the memory device 126 includes a layer stack that is includes a flat section over and/or on the bottom contact 128, and curved sections that extend outward from the flat section. The bottom contact 128 is in an ILD layer 114a. The curvature in the layer stack may result from the process of exposing the bottom contact 128 through the ESL 116a. The ESL 116a is etched to remove a portion of the ESL 116a over the bottom contact 128, resulting in rounded edges in the ESL 116a.

The layer stack of the memory device 126 includes a barrier layer 134 over and/or on the bottom contact 128, a bottom electrode 136 over and/or on the barrier layer 134, a resistive memory layer 138 over and/or on the bottom electrode 136, and a top electrode 140 over and/or on the resistive memory layer 138. In some implementations, the barrier layer 134, the bottom electrode 136, the resistive memory layer 138, and/or the top electrode 140 extend over the rounded edges in the ESL 116a, as shown in FIGS. 1B and 1C. Alternatively, the portions of the barrier layer 134, the bottom electrode 136, the resistive memory layer 138, and/or the top electrode 140 over the rounded edges of the ESL 116a may be removed such that the layer stack of the memory device 126 includes only the flat section that is over the bottom contact 128.

To set the memory device 126 to the LRS, a set operation may be performed in which a set voltage may be applied from the top electrode 140 to the bottom electrode 136 across the resistive memory layer 138. The set voltage causes oxygen atoms in the resistive memory layer 138 to be captured in the top electrode 140, resulting in formation of oxygen vacancies in the resistive memory layer 138. An electric field from the set voltage causes the oxygen vacancies to migrate toward the bottom electrode 136 and to form a conductive filament at the bottom of the resistive memory layer 138. Forming the conductive filament transitions the resistive memory layer 138 (and thus, the memory device 126) to the LRS.

To reset the memory device 126, a reset operation may be performed in which a reset voltage may be applied from the top electrode 140 to the bottom electrode 136. The reset voltage reverses the process by which the conductive filament is formed such that the oxygen atoms in the top electrode 140 combine with the oxygen vacancies in the conductive filament in the resistive memory layer 138. The oxygen recombination of the oxygen atoms with the oxygen vacancies transitions the resistive memory layer 138 (and thus, the memory device 126) to the HRS.

The barrier layer 134 includes tantalum nitride (TaN), titanium nitride (TiN), and/or another material that resists migration of materials (e.g., copper) between the bottom contact 128 and the bottom electrode 136.

The bottom electrode 136 includes one or more electrically conductive materials. In some implementations, the bottom electrode 136 includes a chemically inert electrically conductive material such as a chemically inert metal and/or a chemically inert metal compound. As used herein, “chemically inert” is to be broadly construed to refer to, for example, a substance that is not chemically reactive or does not react under certain circumstances and/or in certain substances.

Some examples of chemically inert metals that can be used for the bottom electrode 136 include iridium (Ir) and/or platinum (Pt), among other examples. An example of a chemically inert metal compound that can be used for the bottom electrode 136 includes ruthenium oxide (RuOₓ), where x is in the range of approximately 1.5 to approximately 2.5. An oxygen concentration within the range of approximately 1.5 to approximately 2.5 results in a higher work function for the bottom electrode 136 than ruthenium in a non-compound form. For example, the work function of ruthenium by itself is approximately 4.7 and the work function of ruthenium oxide (e.g., RuO₂) is approximately 5.1, which enables the conductive filament to be formed using fewer oxygen vacancies than with ruthenium by itself. As a result, the amount of electric field needed to transition the resistive memory layer 138 to the LRS is lower than without ruthenium oxide, enabling a lower forming voltage and/or fewer forming voltage pulses (e.g., forming voltage shots) to be used to form the conductive filament through the resistive memory layer 138. In addition, an oxygen concentration within the range of approximately 1.5 to approximately 2.5 results in a material with an increased tendency to acquire electrons (higher redox potential) than other materials, which may facilitate conductive filament formation since the conductive filament is formed when oxygen vacancies migrate toward the bottom electrode 136. Additionally, an oxygen concentration within the range of approximately 1.5 to approximately 2.5 for ruthenium oxide (RuOₓ) may result in lower electrical resistance for the bottom electrode 136, and therefore greater operating efficiency. Ruthenium oxide (RuOₓ) may be more efficient to etch relative to other types of chemically inert materials, which may require more stringent etching process conditions than ruthenium oxide (RuOₓ). As a result, ruthenium oxide (RuOₓ) may provide a larger etch process parameter window than some other materials.

As shown in the close-up view A of the layer stack of the memory device 126 in FIG. 1B, in some implementations, the bottom electrode 136 is a single layer of a chemically inert metal or of a chemically inert metal compound disposed between the barrier layer 134 and the resistive memory layer 138. Alternatively, as shown in the close-up view B of the layer stack of the memory device 126 in FIG. 1C, the bottom electrode 136 is a bi-layer structure including a first conductive layer 136a and second conductive layer 136b on the first conductive layer 136a, where the stack of the first conductive layer 136a and the second conductive layer 136b are disposed between the barrier layer 134 and the resistive memory layer 138. In some implementations, the first conductive layer 136a is ruthenium (Ru) or other metal with a work function higher than ruthenium (Ru), such as, for example, cobalt (Co), copper (Cu), iridium (Ir), platinum (Pt), gold (Au), and/or molybdenum (Mo), and the second conductive layer 136b is ruthenium oxide (RuOₓ), or another metal compound layer including a chemically inert metal.

In some implementations, the work function of the bottom electrode 136 is tuned to control oxygen vacancy formation in the bottom of the resistive memory layer 138 at the interface between the bottom electrode 136 and the resistive memory layer 138. For example, the chemically inert electrically conductive material of the bottom electrode 136 may include a chemically inert electrically conductive material having a high work function, such as a work function that is greater than a work function of ruthenium (Ru) (e.g., greater than approximately 4.7). The high work function of the chemically inert electrically conductive material of the bottom electrode 136 enables the bottom electrode 136 to resist absorption of oxygen atoms from the resistive memory layer 138, which enables the conductive filament to be formed using fewer oxygen vacancies than with a low work function material.

In some implementations, the chemically inert electrically conductive material of the bottom electrode 136 includes ruthenium oxide (RuOₓ), iridium (Ir), platinum (Pt) and/or another electrically conductive pure metal or oxide having a work function that is greater than approximately 4.7. In some implementations, the work function of the chemically inert electrically conductive material of the bottom electrode 136 is included in a range of approximately 5.1 to approximately 5.65. If the work function is less than approximately 5.1, greater current leakage in the memory device 126 may result, which may cause a significant bitline voltage drop, resulting in a need for a greater number of set voltage pulses to reach the required set voltage to achieve the LRS. The need for additional set voltage pulses (e.g. forming voltage shots) may reduce speed and reliability of the memory device 126. If the work function is greater than approximately 5.65, the memory device 126 may not be operable using lower forming voltages. If the work function is included in the range of approximately 5.1 to approximately 5.65, the memory device 126 may be operated with lower forming voltages while reducing current leakage. However, other values for the work function of the bottom electrode 136, and ranges other than approximately 5.1 to approximately 5.65, are within the scope of the present disclosure.

The resistive memory layer 138 includes one or more resistive memory materials. The one or more resistive memory materials may include one or more high dielectric constant (high-k) dielectric materials, such as one or more dielectric materials having a dielectric constant that is greater than approximately 3.9. In some implementations, the resistive memory layer 138 includes an oxide-containing dielectric material, which enables the resistivity of the resistive memory layer 138 to be modified based on the absence or presence of oxygen vacancies in the resistive memory layer 138. Examples of high-k dielectric materials that may be included in the resistive memory layer 138 include tantalum oxide (TaO), hafnium oxide (HfOₓ such as HfO₂), aluminum oxide (AlₓO_{y} such as Al₂O₃), zirconium oxide (ZrOₓ such as ZrO₂) and/or another material that includes oxygen (O), and/or one or more other elements.

As further shown in the close-up view A and in the close-up view B of the layer stack of the memory device 126, the top electrode 140 may include a plurality of layers, such as a capping layer 140a over and/or on the resistive memory layer 138, and a metal layer 140b over and/or on the capping layer 140a. The capping layer 140a includes, for example, a thin layer of tantalum nitride (TaN) or titanium nitride (TiN) and/or another metal nitride material. The metal layer 140b includes a layer of tantalum (Ta), titanium (Ti) and/or another metal material. The nitrogen concentration in capping layer 140a may be selected to achieve a low set voltage for the memory device 126.

As further shown in the close-up view A and in the close-up view B of the layer stack of the memory device 126, the bottom electrode 136 may have a dimension D1 corresponding to a thickness of the bottom electrode 136, the resistive memory layer 138 may have a dimension D2 corresponding to a thickness of the resistive memory layer 138, and the top electrode 140 may have a dimension D3 corresponding to a thickness of the top electrode 140. In addition, the first conductive layer 136a and the second conductive layer 136b of the bottom electrode 136 may have dimensions D4 and D5, respectively, corresponding to thicknesses of the first conductive layer 136a and the second conductive layer 136b. The dimensions D4 and D5, when added together, are equal to the dimension D1. In some implementations, the dimension D1 is included in a range of approximately 50 angstroms to approximately 200 angstroms. If the dimension D1 is less than approximately 50 angstroms, logic data retention in the memory device 126 may suffer. If the dimension D1 is greater than approximately 200 angstroms, the height or thickness of the memory device 126 may be unnecessarily increased. If the dimension D1 is included in the range of approximately 50 angstroms to approximately 200 angstroms, the height or thickness of the memory device 126 may enable the memory device 126 to be included in smaller form-factor semiconductor devices while achieving a suitable logic data retention performance for the memory device 126. However, other values for the dimension D1, and ranges other than approximately 50 angstroms to approximately 200 angstroms, are within the scope of the present disclosure.

In some implementations, the dimension D4 is included in a range of approximately 50 angstroms to approximately 150 angstroms. If the dimension D4 is less than approximately 50 angstroms, logic data retention in the memory device 126 may suffer. If the dimension D4 is greater than approximately 150 angstroms, the height or thickness of the memory device 126 may be unnecessarily increased. If the dimension D4 is included in the range of approximately 50 angstroms to approximately 150 angstroms, the height or thickness of the memory device 126 may enable the memory device 126 to be included in smaller form-factor semiconductor devices while achieving a suitable logic data retention performance for the memory device 126. However, other values for the dimension D4, and ranges other than approximately 50 angstroms to approximately 150 angstroms, are within the scope of the present disclosure.

In some implementations, the dimension D5 is included in a range of approximately 50 angstroms to approximately 150 angstroms. If the dimension D5 is less than approximately 50 angstroms, greater current leakage in the memory device 126 may result, which may cause a significant bitline voltage drop, resulting in a need for a greater number of set voltage pulses to reach the required set voltage to achieve the LRS. In addition, if the dimension D5 is less than approximately 50 angstroms, logic data retention in the memory device 126 may suffer. If the dimension D5 is greater than approximately 150 angstroms, the height or thickness of the memory device 126 may be unnecessarily increased. If the dimension D5 is included in the range of approximately 50 angstroms to approximately 150 angstroms, the height or thickness of the memory device 126 may enable the memory device 126 to be included in smaller form-factor semiconductor devices while achieving a suitable logic data retention performance and reduced current leakage for the memory device 126. However, other values for the dimension D5, and ranges other than approximately 50 angstroms to approximately 150 angstroms, are within the scope of the present disclosure.

In some implementations, the dimension D2 is included in a range of approximately 16 angstroms to approximately 60 angstroms. If the dimension D2 is lesser than approximately 16 angstroms, the memory device 126 may suffer from reduced endurance (e.g., may experience failure at a lesser quantity of set-reset cycles) and/or increased current leakage. If the dimension D2 is greater than approximately 60 angstroms, the memory device 126 may not operate at lower set voltages. If the dimension D2 is included in the range of approximately 16 angstroms to approximately 60 angstroms, a low set voltage can be used for the memory device 126 while enabling a sufficient endurance performance and/or a low current leakage to be achieved for the memory device 126. However, other values for the dimension D2, and ranges other than approximately 16 angstroms to approximately 60 angstroms, are within the scope of the present disclosure.

In some implementations, the dimension D3 is included in a range of approximately 50 angstroms to approximately 150 angstroms. If the dimension D3 is less than approximately 50 angstroms, the memory device 126 may not operate at lower set voltages. If the dimension D3 is greater than approximately 150 angstroms, the height or thickness of the memory device 126 may be unnecessarily increased. If the dimension D3 is included in the range of approximately 50 angstroms to approximately 150 angstroms, the height or thickness of the memory device 126 may enable the memory device 126 to be included in smaller form-factor semiconductor devices while enabling a low set voltage to be used for the memory device 126. However, other values for the dimension D3, and ranges other than approximately 50 angstroms to approximately 150 angstroms, are within the scope of the present disclosure.

As further shown in FIGS. 1B and 1C, the layer stack of the memory device 126 may be covered by one or more protective layers and/or structures. These protective layers and/or structures may be included to electrically insulate the memory device 126, to protect the memory device 126 from exposure to oxygen and other contaminants, and/or to thermally protect the memory device 126, among other examples. A hard mask layer 142 may be included over and/or on the top electrode 140. The hard mask layer 142 may surround the via 130 that is coupled with the top electrode 140. The hard mask layer 142 may include a silicon oxynitride (SiON), a silicon carbide (SiC), and/or another suitable dielectric mask material.

Sidewall spacers 144 may be included on sidewalls of the top electrode 140 and on sidewalls of the hard mask layer 142. The sidewall spacers 144 may include a silicon nitride (SiₓN_{y} such as Si₃N₄), silicon carbide (SiC), and/or another dielectric spacer material. A nitride re-capping layer 146 may be included over the memory device 126. The nitride re-capping layer 146 may include a silicon nitride (SiₓN_{y} such as Si₃N₄) and/or another nitride-containing dielectric material. The nitride re-capping layer 146 may provide an etch stop layer for etching the recess in which the via 130 is formed.

As shown in FIGS. 1B and 1C, the via 130 is formed in an ILD layer 114b, which is formed on the ESL 116a and around the memory device 126. Another ESL 116b is formed on the ILD layer 114b, and another ILD layer 114c is formed on the ESL 116b. The top contact 132 is formed in the ILD layer 114c and in the ESL 116b. The top contact 132 lands on and contacts a top surface of the via 130.

As indicated above, FIGS. 1A-1C are provided as examples. Other examples may differ from what is described with regard to FIGS. 1A-1C.

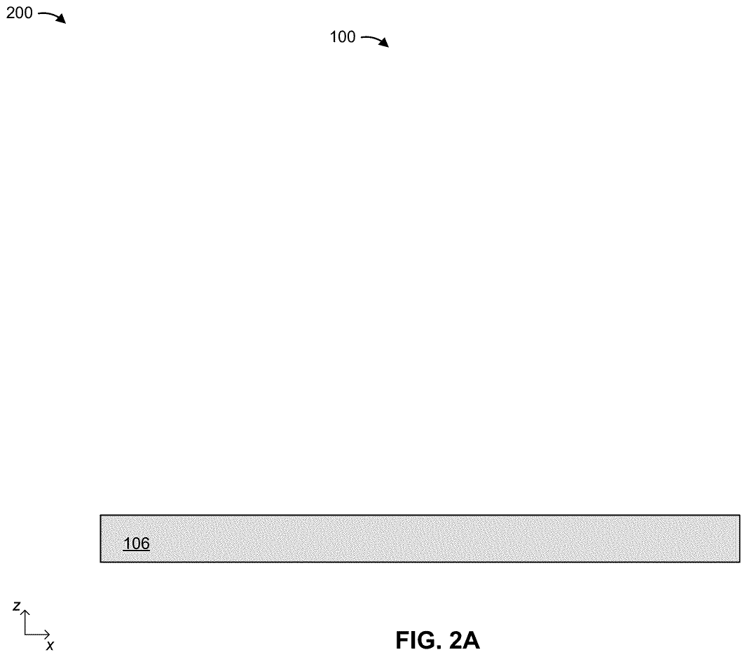

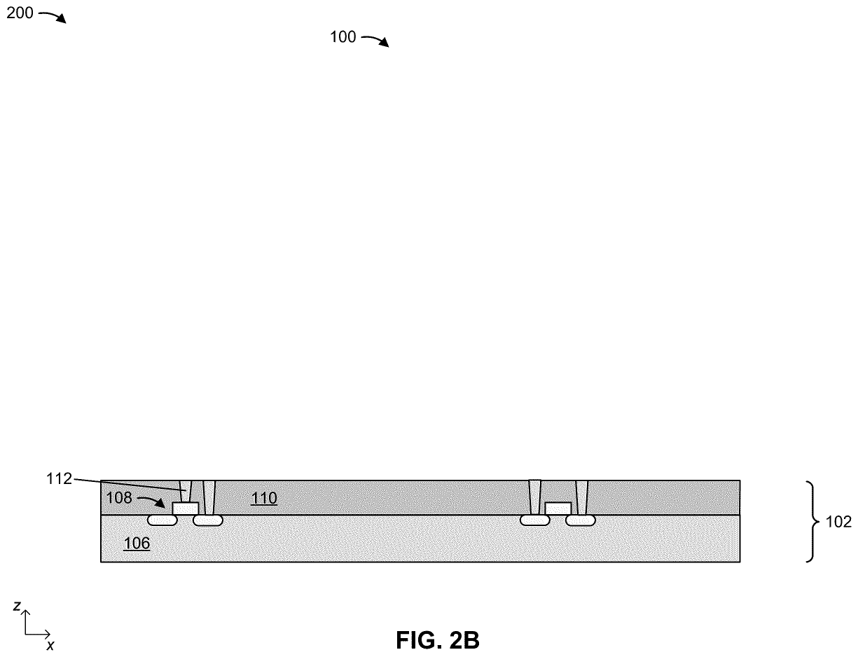

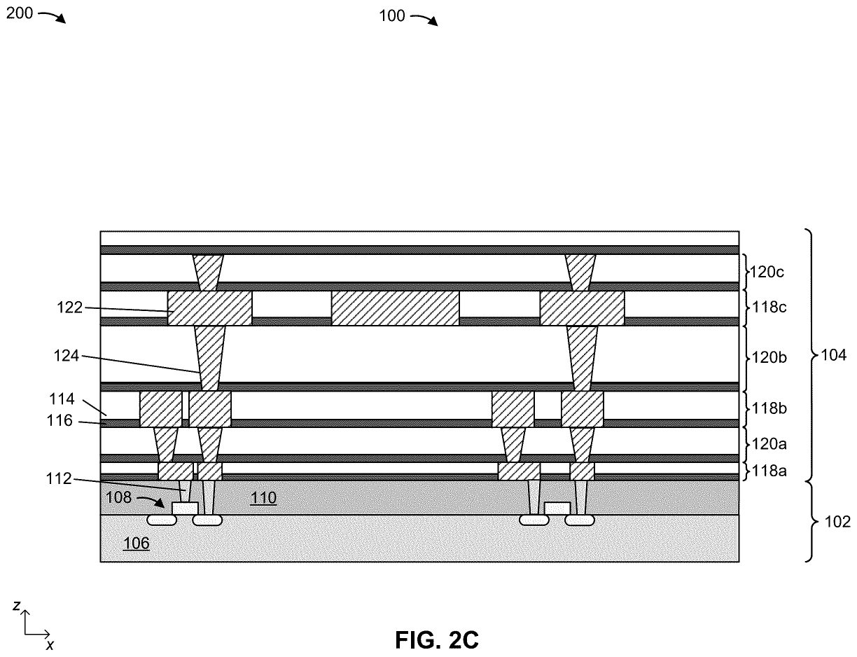

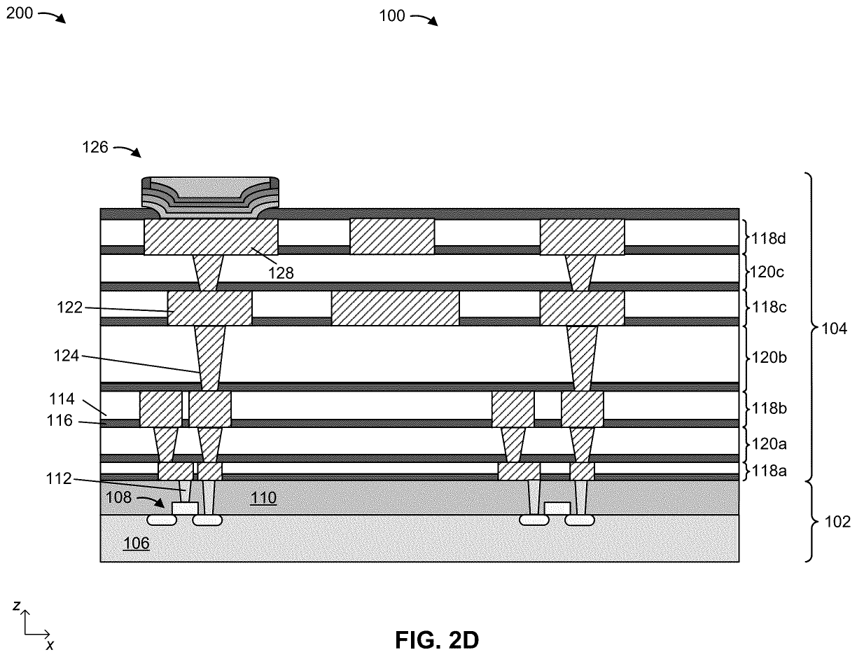

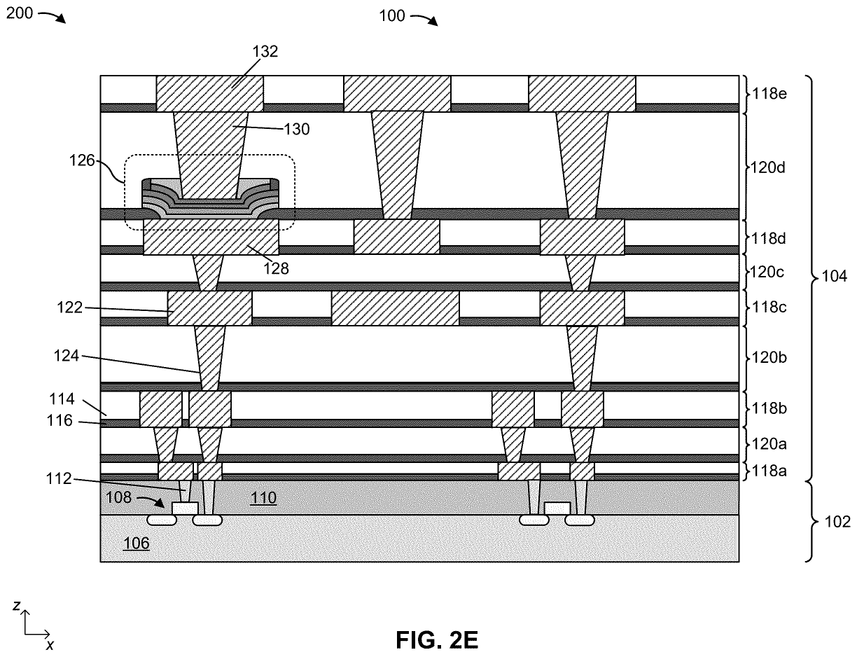

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the

dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 2C, a deposition tool, an exposure tool, a developer tool, an etch tool, a planarization tool, a plating tool, and/or another semiconductor processing tool may be used to perform various operations to form the metallization structures 122 and to form the interconnect structures 124 in the first portion of the interconnect layer 104 of the semiconductor device 100.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b, 118c, 120b, and 120c may be formed in a similar manner.

One or more deposition tools may be used to deposit the metallization structures 122, the interconnect structures 124, and/or the bottom contact 128 using a PVD technique, an ALD technique, a CVD technique, an electroplating technique (e.g., an electro-chemical plating technique), and/or another suitable deposition technique. In some implementations, a planarization tool may be used to planarize the metallization structures 122 and/or the interconnect structures 124 after the metallization structures 122 and/or the interconnect structures 124 are deposited.

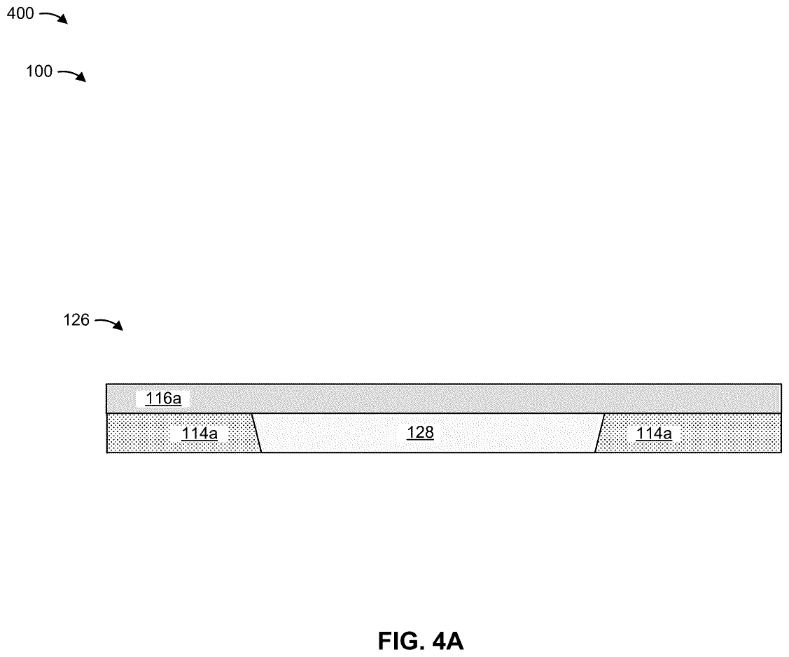

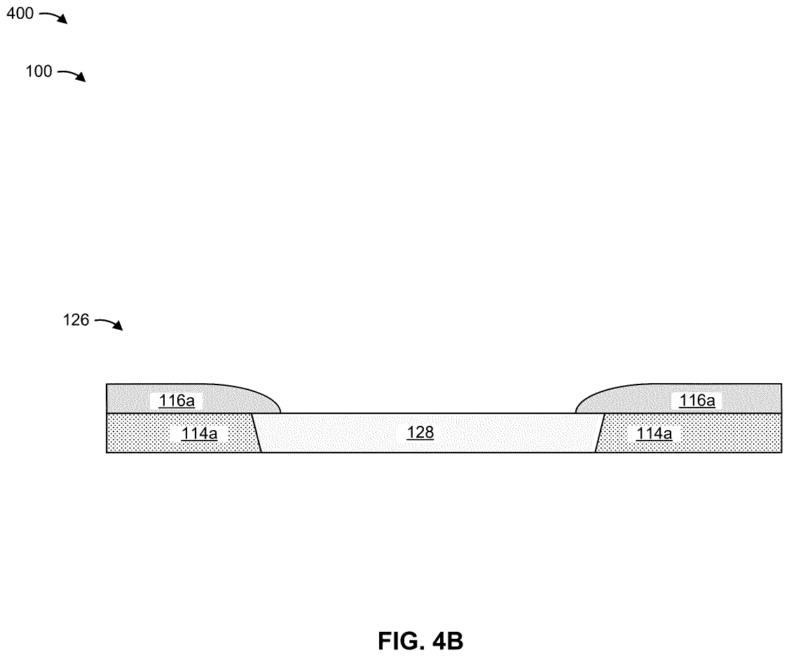

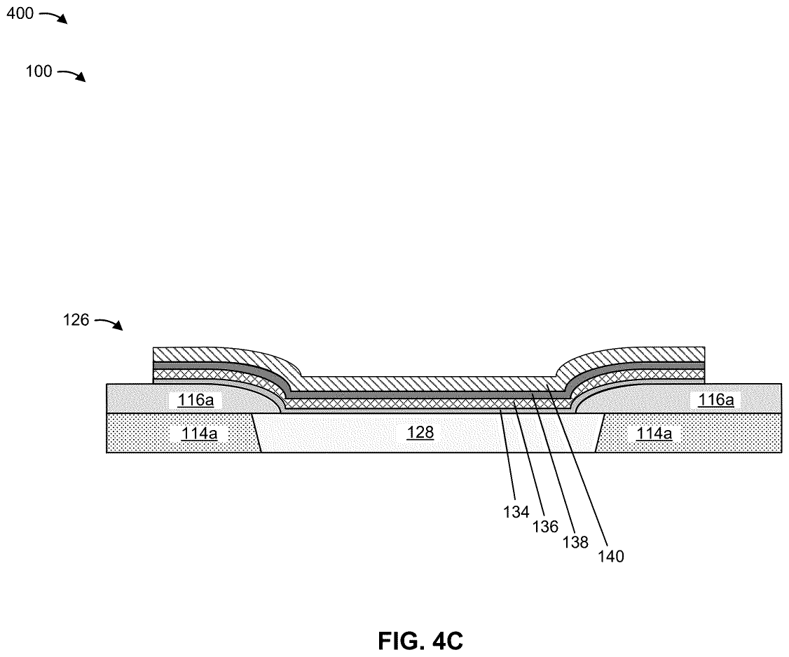

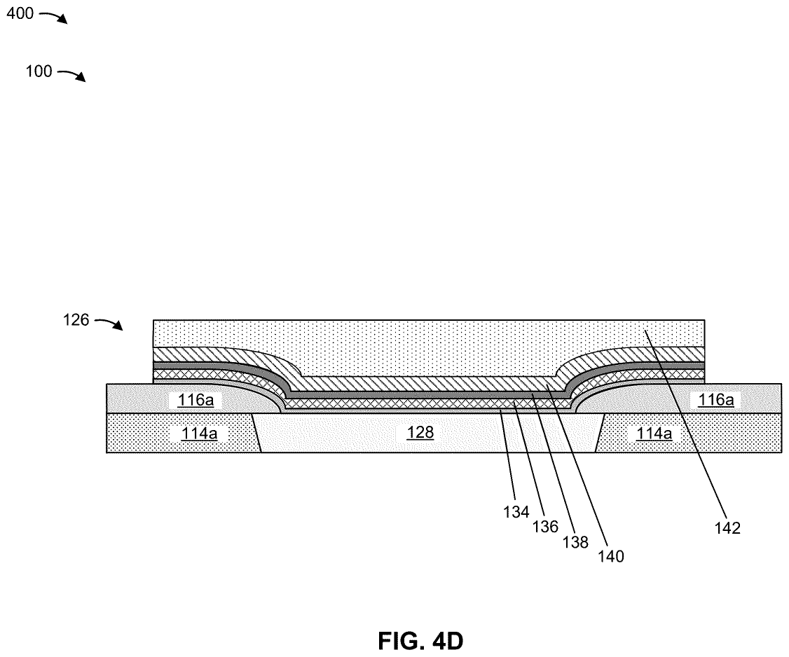

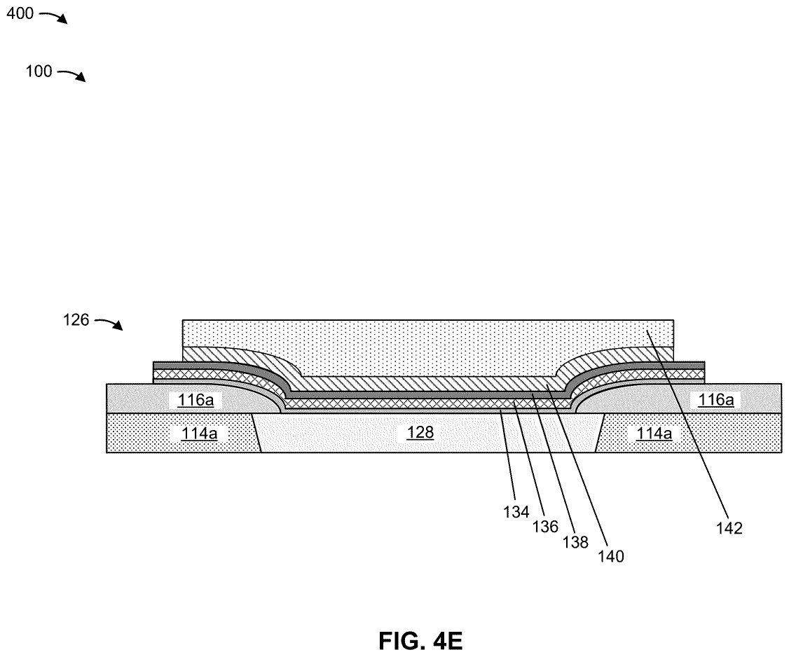

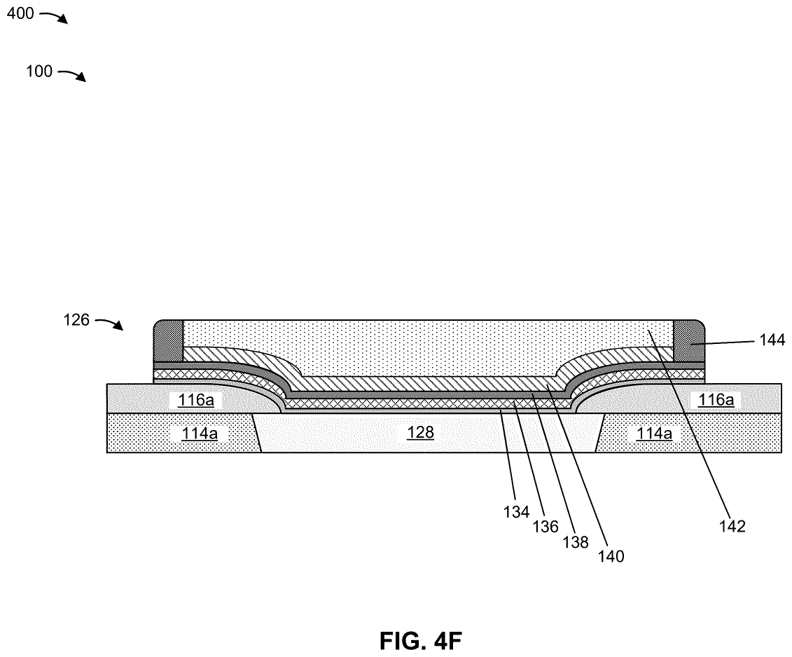

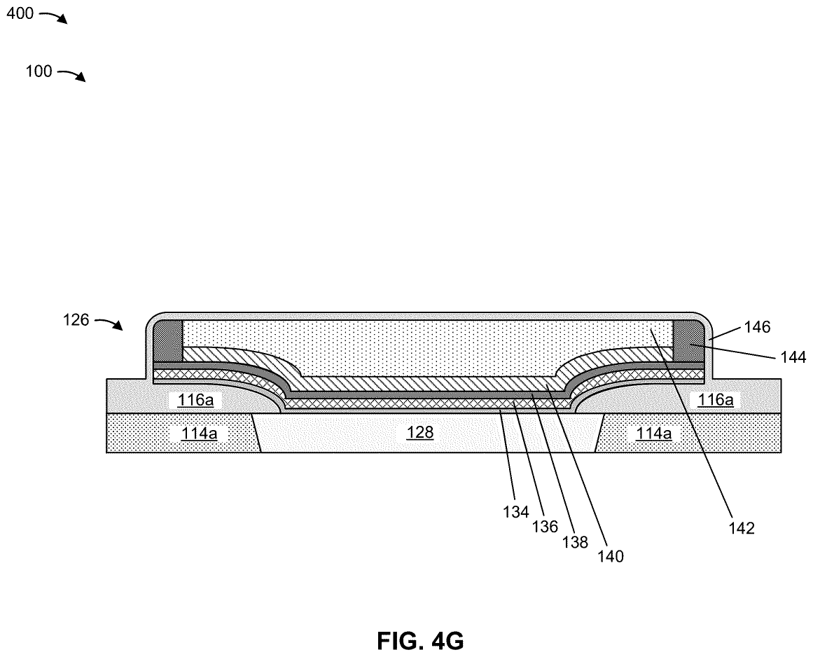

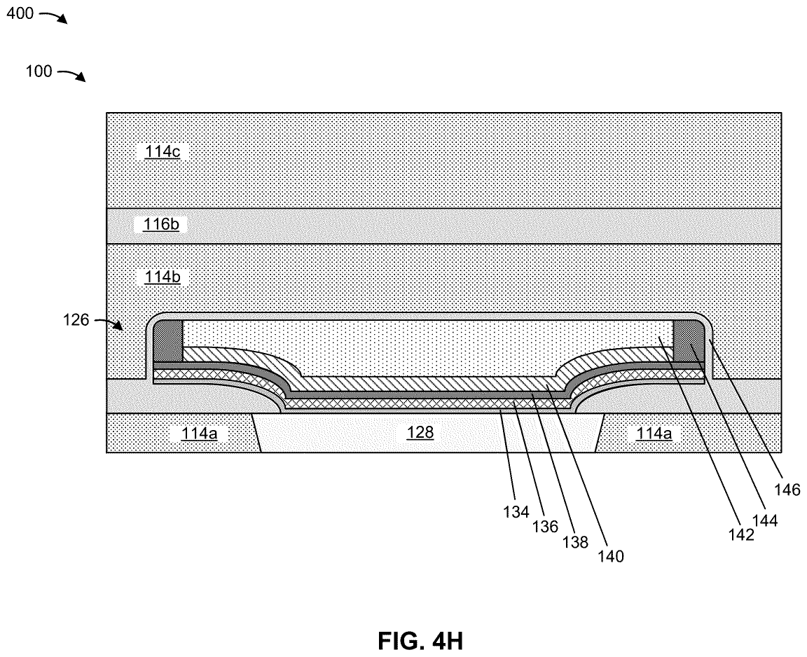

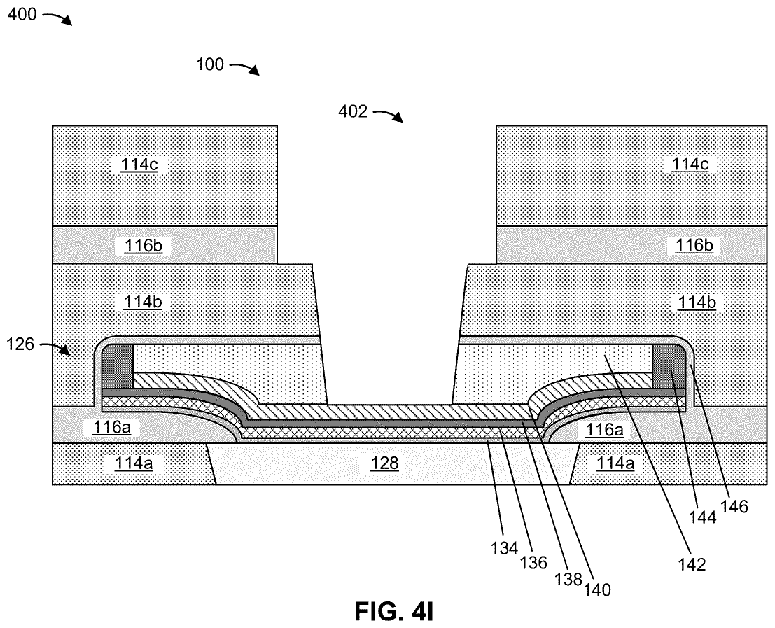

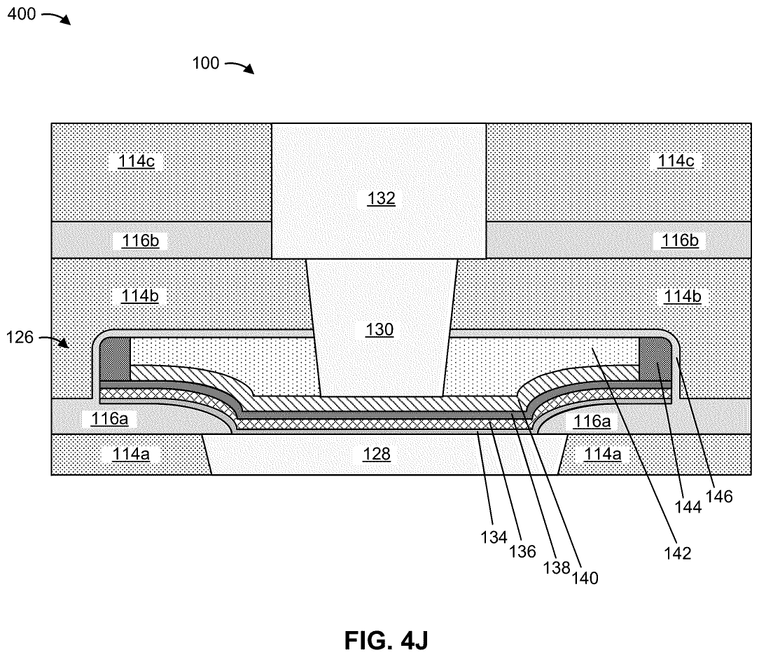

As shown in FIG. 2D, a memory device 126 may be formed on and in an ESL 116 in the interconnect layer 104. The memory device 126 may be formed such that the barrier layer 134 of the memory device 126 lands on the bottom contact 128 in the interconnect layer 104. An example process for forming the memory device 126 is illustrated and described in connection with FIGS. 4A-4J.

As shown in FIG. 2E, a second portion of the interconnect layer 104 of the semiconductor device 100 is formed above the first portion of the interconnect layer 104, including above and around the memory device 126. The second portion of the interconnect layer 104 may be formed in a similar manner as the first portion of the interconnect layer 104, as described in connection with FIG. 2C. The via 130 and top contact 132 of the memory device 126 may be formed in the second portion of the interconnect layer 104.

As indicated above, FIGS. 2A-2E are provided as an example. Other examples may differ from what is described with regard to FIGS. 2A-2E.

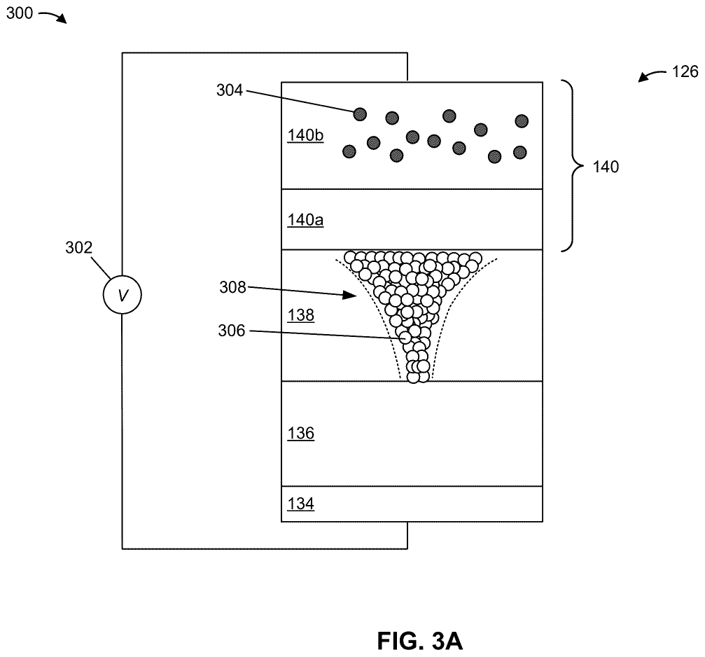

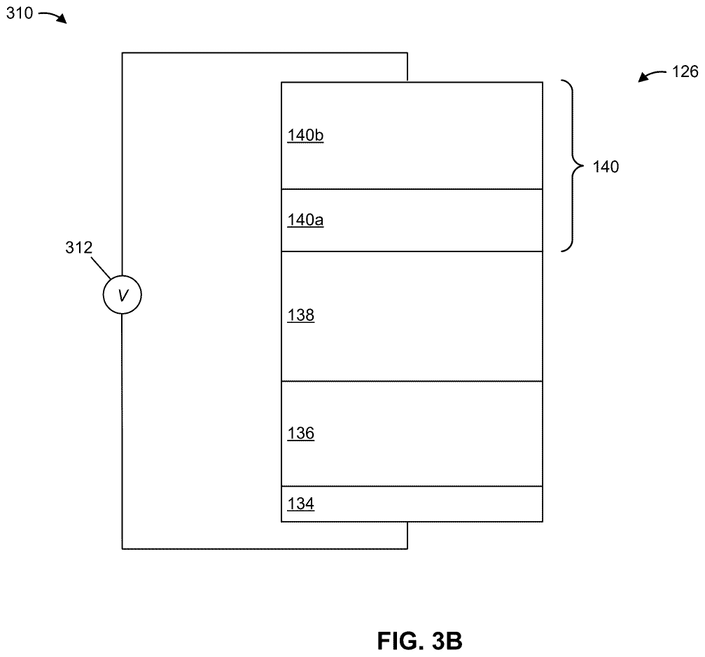

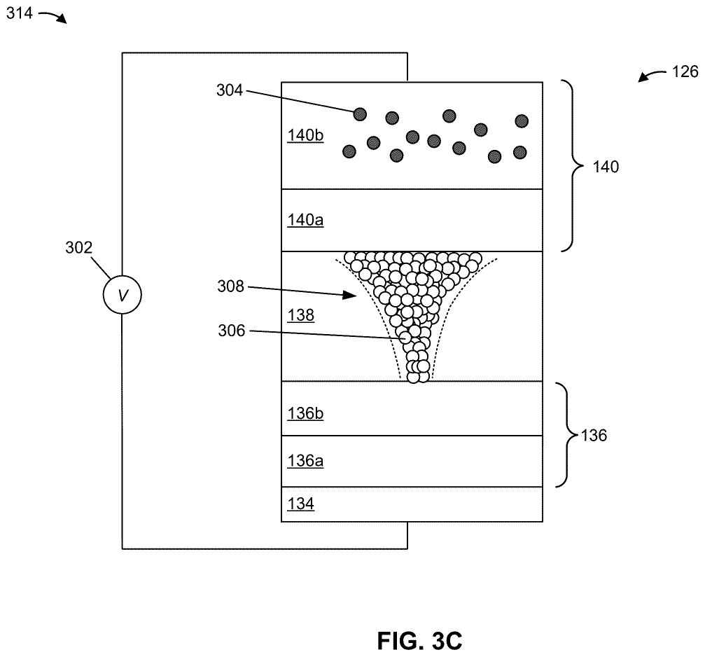

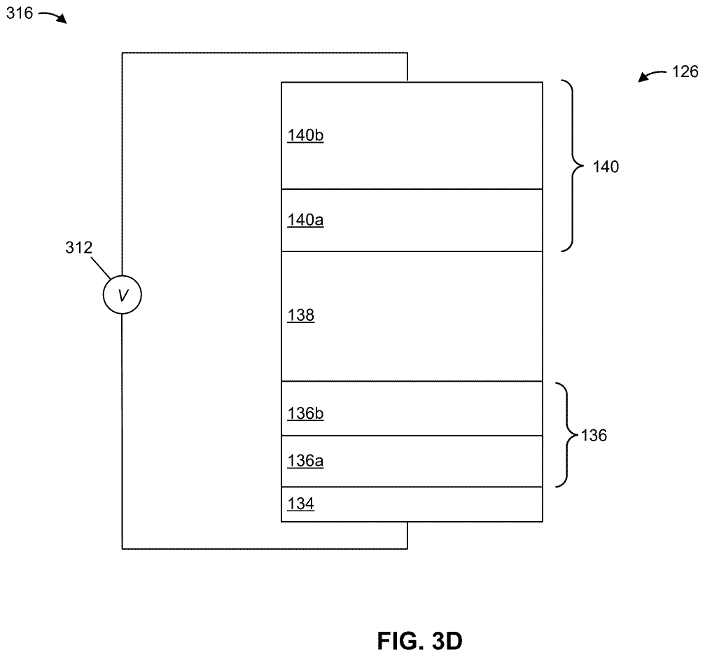

FIGS. 3A-3D are diagrams illustrating example implementations of operations of the memory device 126 described herein. FIG. 3A illustrates an example implementation 300 of a set operation in which a conductive filament is formed in the memory device 126, where the bottom electrode 136 is a single layer (e.g., a ruthenium oxide (RuOₓ) layer, an iridium (Ir) layer or a platinum (Pt) layer). FIG. 3B illustrates an example implementation 310 of a reset operation in which the conductive filament is removed from the memory device 126, where the bottom electrode 136 is a single layer. FIG. 3C illustrates an example implementation 314 of a set operation in which a conductive filament is formed in the memory device 126, where the bottom electrode 136 includes the first conductive layer 136a (e.g., a ruthenium layer) and the second conductive layer 136b (e.g., a ruthenium oxide (RuOₓ) layer). FIG. 3D illustrates an example implementation 316 of a reset operation in which the conductive filament is removed from the memory device 126, where the bottom electrode 136 includes the first conductive layer 136a (e.g., a ruthenium layer) and the second conductive layer 136b. The conductive filament may be selectively formed in the resistive memory layer 138 to selectively store one or more bits of electronic data based on an electrical resistance of the resistive memory layer 138.

As shown in FIG. 3A, the resistive memory layer 138 may be selectively set to an LRS to store a first logical value (e.g., a 0-value or a 1-value) by applying a set voltage 302 (also referred to as a forming voltage) across the top electrode 140 and the bottom electrode 136. The set voltage causes oxygen atoms 304 from the resistive memory layer 138 to be captured in one or more layers 140a and 140b of the top electrode 140, resulting in formation of oxygen vacancies 306 in the resistive memory layer 138. An electric field from the set voltage 302 causes the oxygen vacancies 306 to form a conductive filament 308 through the resistive memory layer 138. The conductive filament 308 provides a path of electrical conductivity between the bottom electrode 136 and the top electrode 140 through the resistive memory layer 138.

As further shown in FIG. 3A, the cross-sectional profile of the conductive filament 308 may be tapered or curved between the bottom electrode 136 and the top electrode 140. The tapered or curved cross-sectional profile results in a conical (e.g., cone-shaped) three-dimensional shape for the conductive filament 308. In particular, the cross-sectional width of the conductive filament 308 may be greater at the top of the resistive memory layer 138 near the top electrode 140 (e.g., adjacent the capping layer 140a) than the cross-sectional width of the conductive filament 308 at the bottom of the resistive memory layer 138 near the bottom electrode 136. The cross-sectional width of the conductive filament 308 may decrease from the top of the resistive memory layer 138 to the bottom of the resistive memory layer 138.

The tapered cross-sectional profile (and the associated conical three-dimensional shape) of the conductive filament 308 results from the concentration of oxygen vacancies 306 being greater at the top of the resistive memory layer 138 than the concentration of oxygen vacancies 306 at the bottom of the resistive memory layer 138. The tapered cross-sectional profile may result from the high work function of the material of the bottom electrode 136. In particular, the high work function of the material of the bottom electrode 136 (e.g., ruthenium oxide (RuOₓ), iridium (Ir), or platinum (Pt)) results in a low oxygen affinity in the bottom electrode 136, which enables the bottom electrode 136 to resist oxygen absorption from the resistive memory layer 138.

As shown in FIG. 3B, a reset voltage 312 may be applied across the bottom electrode 136 and the top electrode 140 to dissipate the conductive filament 308 in the resistive memory layer 138. The reset voltage 312 causes the oxygen atoms 304 captured in the top electrode 140 to recombine with the oxygen vacancies 306 in the resistive memory layer 138, resulting in a high electrical resistance in the resistive memory layer 138.

The tapered cross-sectional profile (and the associated conical three-dimensional shape) of the conductive filament 308 enables the oxygen vacancies 306 to be more effectively and fully removed from the resistive memory layer 138 than other cross-sectional and/or three-dimensional profiles for the conductive filament 308. For example, if an hour-glass three-dimensional shape were implemented in a conductive filament in a memory device (e.g., where the concentration of oxygen vacancies increases toward a top electrode and toward a bottom electrode of the memory device), the greater concentration of oxygen vacancies further down into the resistive memory layer results in difficulty in recombining those oxygen vacancies with

oxygen atoms from the top electrode. This may result in residual oxygen vacancies in the resistive memory layer that, as set-reset cycles are accumulated for the memory device, may cause endurance issues for the memory device. By forming a narrow conductive filament 308 at the bottom of the resistive memory layer 138 near the bottom electrode 136, as implemented in the tapered cross-sectional profile (and the associated conical three-dimensional shape) of the conductive filament 308 of the memory device 126, fewer oxygen vacancies 306 need to be removed from the bottom of the resistive memory layer 138 in order to dissipate the conductive filament 308. This results in a reduced likelihood that residual oxygen vacancies are accumulated in the resistive memory layer 138, which increases the endurance of the memory device 126 for the memory device 126, among other examples.

In this way, a lower magnitude reset voltage may be used, which enables increased endurance to be achieved for the memory device 126. Alternatively, a reset voltage approximately matching the magnitude of the set voltage may be used due to improving oxygen and oxygen vacancy recombination by high work function of the material for the bottom electrode 136.

Similar to what is shown in FIG. 3A, as shown in FIG. 3C, the resistive memory layer 138 may be selectively set to an LRS to store a first logical value (e.g., a 0-value or a 1-value) by applying the set voltage 302 (also referred to as a forming voltage) across the top electrode 140 and the bottom electrode 136. The conductive filament 308, which includes the oxygen vacancies 306, provides a path of electrical conductivity between the bottom electrode 136 and the top electrode 140 through the resistive memory layer 138. The bottom electrode in the implementation in FIG. 3C includes the first conductive layer 136a and the second conductive layer 136b. The cross-sectional width of the conductive filament 308 may be greater at the top of the resistive memory layer 138 near the top electrode 140 (e.g., adjacent the capping layer 140a) than the cross-sectional width of the conductive filament 308 at the bottom of the resistive memory layer 138 near the bottom electrode 136 (e.g., adjacent the second conductive layer 136b). The tapered cross-sectional profile may result from the high work function of the material of the bottom electrode 136. In particular, the high work function of the material of the second conductive layer 136b (e.g., ruthenium oxide (RuOₓ)) of the bottom electrode 136 results in a low oxygen affinity in the bottom electrode 136, which enables the bottom electrode 136 to resist oxygen absorption from the resistive memory layer 138.

Similar to what is shown in FIG. 3B, as shown in FIG. 3D, a reset voltage 312 may be applied across the bottom electrode 136 and the top electrode 140 to dissipate the conductive filament 308 in the resistive memory layer 138. The reset voltage 312 causes the oxygen atoms 304 captured in the top electrode 140 to recombine with the oxygen vacancies 306 in the resistive memory layer 138, resulting in a high electrical resistance in the resistive memory layer 138.

By forming a narrow conductive filament 308 at the bottom of the resistive memory layer 138 near the second conductive layer 136b of the bottom electrode 136, as implemented in the tapered cross-sectional profile (and the associated conical three-dimensional shape) of the conductive filament 308 of the memory device 126, fewer oxygen vacancies 306 need to be removed from the bottom of the resistive memory layer 138 in order to dissipate the conductive filament 308. In this way, a lower magnitude reset voltage may be used, which enables increased endurance to be achieved for the memory device 126. Alternatively, a reset voltage approximately matching the magnitude of the set voltage may be used due to improving oxygen and oxygen vacancy recombination by the high work function of the material of the second conductive layer 136b.

As indicated above, FIGS. 3A-3D are provided as examples. Other examples may differ from what is described with regard to FIGS. 3A-3D.

FIGS. 4A-4J are diagrams of an example implementation 400 of forming the memory device 126 described herein. In some implementations, one or more semiconductor processing tools may be used to perform one or more of the semiconductor processing operations described in connection with FIGS. 4A-4J, such as a deposition tool, an exposure tool, a developer tool, an etch tool, a planarization tool, an ion implantation tool, a wafer/die transport tool, and/or another type of semiconductor processing tool.

Turning to FIG. 4A, the memory device 126 may be formed in the interconnect region of the semiconductor device 100. The memory device 126 may be formed above the bottom contact 128 and/or another metallization layer in the interconnect region of the semiconductor device 100.

As shown in FIG. 4B, an opening may be formed through the ESL 116a to expose the top surface of the bottom contact 128. In some implementations, a pattern in a photoresist layer is used to etch the ESL 116a to form the opening through the ESL 116a. In these

implementations, a deposition tool may be used to form the photoresist layer on the ESL 116a. An exposure tool may be used to expose the photoresist layer to a radiation source to pattern the photoresist layer. A developer tool may be used to develop and remove portions of the photoresist layer to expose the pattern. An etch tool may be used to etch the ESL 116a based on the pattern to form the opening through the ESL 116a. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ESL 116a based on a pattern.

As shown in FIG. 4C, the layer stack of the memory device 126 is formed over and/or on the bottom contact 128. In some implementations, portions of the layer stack extend onto the ESL 116a. In some implementations, these portions are subsequently removed.

As shown in FIG. 4C, the barrier layer 134 may be formed over and/or on the top surface of the bottom contact 128. A deposition tool may be used to deposit the barrier layer 134 using a PVD technique, an ALD technique, a CVD technique, an oxidation technique, and/or another suitable deposition technique.

The bottom electrode 136 may be formed over and/or on the barrier layer 134. A deposition tool may be used to deposit the bottom electrode 136 using a CVD technique, a PVD technique (e.g., a sputter technique), an ALD technique, an electroplating technique, and/or another suitable technique operation.

In the case of using a sputter technique, forming the bottom electrode 136 may include positioning the semiconductor device 100 on a chuck in a processing chamber of a deposition tool. A target material (e.g., a ruthenium (Ru) target material) is also included in the processing chamber. A process gas (e.g., an oxygen (O) process gas) is provided into the processing chamber, and a plasma is generated in the processing chamber. Ions in the plasma are accelerated toward the target material to generate a sputtered material that is deposited onto the semiconductor device 100. The initial flow-in of the process gas reacts with the sputtered material and results in the deposition of the metal compound layer (e.g., ruthenium oxide (RuOₓ)) on the barrier layer 134 or on the first conductive layer 136a. In some implementations, a metal oxide layer (e.g., ruthenium oxide (RuOₓ)) may be deposited on the barrier layer 134 or on the first conductive layer 136a using a plasma-enhanced chemical vapor deposition (PECVD) deposition technique.

In some implementations, in order to form a multi-layer structure as the bottom electrode 136 including the first conductive layer 136a and the second conductive layer 136b, a metal layer (e.g., ruthenium (Ru)) may be deposited on the barrier layer 134 using, for example, a CVD or sputtering deposition process. Then, a thermal oxidation process is performed to oxidize a portion of the metal layer. The portion of the metal layer that is oxidized results in a metal oxide layer as the second conductive layer 136b on the portion of the metal layer that is not oxidized (e.g., first conductive layer 136a). In some implementations, the thermal oxidation process is performed at a temperature included in the range of approximately 400 degrees Celsius to approximately 600 degrees Celsius. However, other values for the temperature are within the scope of the present disclosure. A second conductive layer 136b including a metal oxide formed by a thermal oxidation process may exhibit lower leakage current than a second conductive layer 136b deposited using, for example, CVD (e.g., PECVD) or sputtering deposition techniques.

In some implementations, a multi-layer structure for the bottom electrode 136 may include more than two conductive layers. For example, the multi-layer structure may include three or more conductive layers, where a metal compound layer (e.g., ruthenium oxide (RuOₓ)) is formed on two or more underlying metal layers (e.g., ruthenium (Ru) or other metal with a work function higher than ruthenium (Ru)), or on a combination of one or more metal layers and one or more metal compound layers. In some implementations, a multi-layer structure for the bottom electrode 136 may include two or more metal compound layers.

The resistive memory layer 138 may be formed over and/or on the bottom electrode 136. A deposition tool may be used to deposit the resistive memory layer 138 using a PVD technique, an ALD technique, a CVD technique, an oxidation technique, and/or another suitable deposition technique. In the case of a multi-layer structure as the bottom electrode 136 including the first conductive layer 136a and the second conductive layer 136b, or more than two conductive layers, the uppermost conductive layer including a metal compound layer may be in contact with the resistive memory layer 138.

The top electrode 140 is formed over and/or on the resistive memory layer 138. A deposition tool may be used to form the top electrode 140 using a PVD technique such as a sputter deposition technique. Forming the top electrode 140 includes positioning the semiconductor device 100 on a chuck in a processing chamber of a deposition tool. A target material (e.g., a tantalum (Ta) or titanium (Ti) target material) is also included in the processing chamber. A process gas (e.g., a nitrogen (N) process gas) is provided into the processing chamber, and a plasma is generated in the processing chamber. Ions in the plasma are accelerated toward the target material to generate a sputtered material that is deposited onto the semiconductor device 100. The initial flow-in of the process gas reacts with the sputtered material and results in the deposition of the capping layer 140a on the resistive memory layer 138. Once the process gas stabilizes in the processing chamber, the sputtered material deposits onto the semiconductor device 100 as the metal layer 140b on the capping layer 140a.

As shown in FIG. 4D, the hard mask layer 142 may be formed over and/or on the layer stack of the memory device 126. A deposition tool may be used to deposit the hard mask layer 142 using a PVD technique, an ALD technique, a CVD technique, an oxidation technique, and/or another suitable deposition technique. In some implementations, a planarization tool may be used to planarize the hard mask layer 142.

As shown in FIG. 4E, portions of the hard mask layer 142 and portions of the top electrode 140 may be removed to expose portions of the top surface of the resistive memory layer 138. In some implementations, a pattern in a photoresist layer is used to etch the hard mask layer 142 and the resistive memory layer 138. In these implementations, a deposition tool may be used to form the photoresist layer on the hard mask layer 142. An exposure tool may be used to expose the photoresist layer to a radiation source to pattern the photoresist layer. A developer tool may be used to develop and remove portions of the photoresist layer to expose the pattern. An etch tool may be used to etch the hard mask layer 142 and the resistive memory layer 138 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the hard mask layer 142 and the resistive memory layer 138 based on a pattern.

As shown in FIG. 4F, sidewall spacers 144 are formed in areas in which the portions of the hard mask layer 142 and the top electrode 140 were removed. A deposition tool may be used to deposit the sidewall spacers 144 using a PVD technique, an ALD technique, a CVD technique, an oxidation technique, and/or another suitable deposition technique.

As shown in FIG. 4G, the nitride re-capping layer 146 is formed over and/or on the hard mask layer 142 and the sidewall spacers 144. The nitride re-capping layer 146 is also formed on sidewalls of the barrier layer 134, the bottom electrode 136, and/or the resistive memory layer 138. A deposition tool may be used to deposit the nitride re-capping layer 146 using a PVD technique, an ALD technique, a CVD technique, an oxidation technique, and/or another suitable deposition technique.

As shown in FIG. 4H, the ILD layer 114b is formed over and/or on the memory device 126. A deposition tool may be used to deposit the ILD layer 114b using a PVD technique, an ALD technique, a CVD technique, an oxidation technique, and/or another suitable deposition technique. In some implementations, a planarization tool may be used to planarize the ILD layer 114b.

The ESL 116b is formed on the ILD layer 114b. A deposition tool may be used to deposit the ESL 116b using a PVD technique, an ALD technique, a CVD technique, an oxidation technique, and/or another suitable deposition technique. In some implementations, a planarization tool may be used to planarize the ESL 116b.

The ILD layer 114c is formed on the ESL 116b. A deposition tool may be used to deposit the ILD layer 114c using a PVD technique, an ALD technique, a CVD technique, an oxidation technique, and/or another suitable deposition technique. In some implementations, a planarization tool may be used to planarize the ILD layer 114c.

As shown in FIG. 4I, a recess 402 is formed through the ILD layer 114c, through the ESL 116b, through the ILD layer 114b, through the nitride re-capping layer 146, and through the hard mask layer 142. The recess 402 is formed over the memory device 126 such that the top surface of the top electrode 140 is exposed through the recess 402. In some implementations, a pattern in a photoresist layer is used to etch through the ILD layer 114c, through the ESL 116b, through the ILD layer 114b, through the nitride re-capping layer 146, and through the hard mask layer 142. In these implementations, a deposition tool may be used to form the photoresist layer on the ILD layer 114c. An exposure tool may be used to expose the photoresist layer to a radiation source to pattern the photoresist layer. A developer tool may be used to develop and remove portions of the photoresist layer to expose the pattern. An etch tool may be used to etch through the ILD layer 114c, through the ESL 116b, through the ILD layer 114b, through the nitride re-capping layer 146, and through the hard mask layer 142 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 402 based on a pattern.

In some implementations, the recess 402 includes a dual damascene recess that includes a via portion and a trench portion. In some implementations, a trench-first process is performed in which the trench portion is formed, followed by formation of the via portion. In some implementations, a via-first process is performed in which the via portion is formed, followed by formation of the trench portion.

As shown in FIG. 4J, the via 130 and the top contact 132 may be formed in the recess 402. The via 130 may be electrically coupled and/or physically coupled with the top electrode 140 of the memory device 126. A deposition tool may be used to deposit the via 130 and the top contact 132 using a CVD technique, a PVD technique, an ALD technique, an electroplating technique, and/or another suitable technique operation. In some implementations, a planarization tool may be used to planarize the top contact 132.

As indicated above, FIGS. 4A-4J are provided as examples. Other examples may differ from what is described with regard to FIGS. 4A-4J.

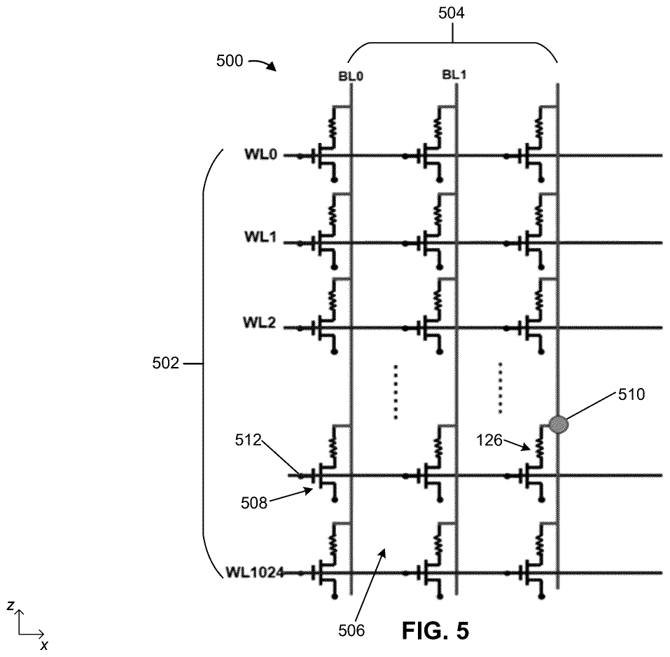

FIG. 5 is a circuit diagram of an array of memory cells each including a memory device described herein. In the circuit diagram 500, the horizontal lines in the x-direction represent wordlines 502 (e.g., WL0, WL1, WL2,. WL1024), and the vertical lines in the z-direction represent bitlines 504 (e.g., BL0, BL1, etc.). The number of wordlines 502 and bitlines 504 may vary from what is shown in FIG. 5, and other values for number of wordlines 502 and bitlines 504 are within the scope of the present disclosure. The wordlines 502 and bitlines 504 may be formed of electrically conductive material such as, for example, tungsten (W), cobalt (Co), ruthenium (Ru), titanium (Ti), aluminum (Al), and/or gold (Au), among other electrically conductive materials. As shown in FIG. 5, the arrangement of the wordlines 502 and the bitlines 504 forms an array of memory cells 506. Each memory cell 506 in the array includes a memory device 126 as described herein. Each memory device 126 in the array may be an RRAM device. Each memory cell 506 in the array further includes a transistor 508 connected to memory device 126 in the memory cell 506.

A bitline voltage 510 (e.g., set or forming voltage) is applied to a memory device 126 to set the memory device 126 to the LRS. As noted herein, increased current leakage can result in significant drops in bitline voltage 510 for a memory cell 506, which may cause an applied voltage to set a memory device 126 to the LRS to be less than the required set voltage, thereby requiring a greater number of voltage pulses to achieve the LRS. The high work function material of the bottom electrode 136 of a memory device 126 described herein reduces current leakage in an RRAM device when compared with an RRAM device without the high work function material. As a result of the reduced current leakage, the bitline voltage 510 to set a memory device 126 to the LRS may correspond to the required set voltage, thereby requiring fewer voltage pulses to achieve the LRS than when a low work function material is used for the bottom electrode 136 of the memory device 126. The reduced number of pulses needed to achieve the LRS increases memory device speed and increases overall device reliability.

A wordline voltage 512 (e.g., select voltage) is applied to the gates of transistors 508 in a row of memory cells 506 to activate the row of memory cells 506 and corresponding memory devices 126 for memory operations (e.g., read and/or write operations). In some situations, memory cells 506 that have not been activated (e.g., have not received a select voltage) may be connected to the same bitline 504 as an activated memory cell 506. The memory cells 506 that have not been activated may cause gate-induced drain leakage (GIDL) (e.g. current leakage), which reduces the bitline voltage 510 applied to the activated memory cell 506 connected to the same bitline 504 as the non-activated memory cells 506. The high work function material of the bottom electrode 136 of a memory device 126 described herein reduces the gate-induced drain leakage (GIDL) when compared with a memory device without the high work function material.

In some implementations, the bitline voltage 510 may be approximately 3.6 volts and the wordline voltage 512 may be approximately 1.5 volts. However, other values for the bitline voltage 510 and the wordline voltage 512 are within the scope of the present disclosure.

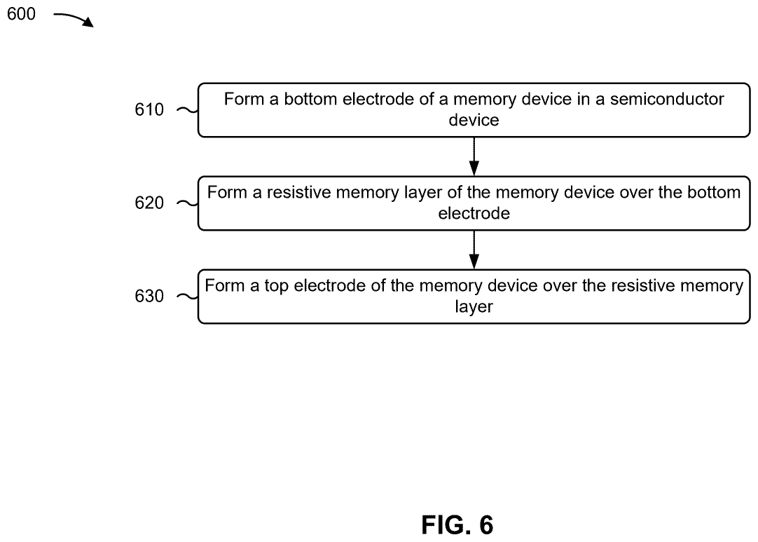

FIG. 6 is a flowchart of an example process 600 associated with forming a semiconductor device. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include forming a bottom electrode of a memory device in a semiconductor device (block 610). For example, one or more semiconductor processing tools may be used to form a bottom electrode (e.g., bottom electrode 136) of a memory device (e.g., memory device 126) in a semiconductor device (e.g., semiconductor device 100), as described herein. In some implementations, the bottom electrode is formed of an electrically conductive material including a metal oxide.

As further shown in FIG. 6, process 600 may include forming a resistive memory layer of the memory device over the bottom electrode (block 620). For example, one or more semiconductor processing tools may be used to form a resistive memory layer (e.g., resistive memory layer 138) of the memory device over the bottom electrode, as described herein.

As further shown in FIG. 6, process 600 may include forming a top electrode of the memory device over the resistive memory layer (block 630). For example, one or more semiconductor processing tools may be used to form a top electrode (e.g., top electrode 140) of the memory device over the resistive memory layer, as described herein.

Process 600 may include additional implementations, such as any single implementation or any combination of implementations described below and/or in connection with one or more other processes described elsewhere herein.

In a first implementation, the electrically conductive material is chemically inert.

In a second implementation, alone or in combination with the first implementation, the electrically conductive material has a work function that is greater than a work function of ruthenium (Ru).

In a third implementation, alone or in combination with one or more of the first and second implementations, the metal oxide includes ruthenium oxide (RuOₓ).

In a fourth implementation, alone or in combination with one or more of the first through third implementations, x in the RuOₓ is included in a range of approximately 1.5 to approximately 2.5.

In a fifth implementation, alone or in combination with one or more of the first through fourth implementations, the bottom electrode includes a bi-layer structure (e.g., first conductive layer 136a and second conductive layer 136b).

In a sixth implementation, alone or in combination with one or more of the first through fifth implementations, the bi-layer structure includes a first layer including a metal (e.g., first conductive layer 136a), and a second layer including the metal oxide (e.g., second conductive layer 136b).

In a seventh implementation, alone or in combination with one or more of the first through sixth implementations, the metal is ruthenium (Ru) and the metal oxide is ruthenium oxide (RuOₓ).

In an eighth implementation, alone or in combination with one or more of the first through seventh implementations, the second layer is formed on the first layer, and the resistive memory layer is formed on the second layer.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

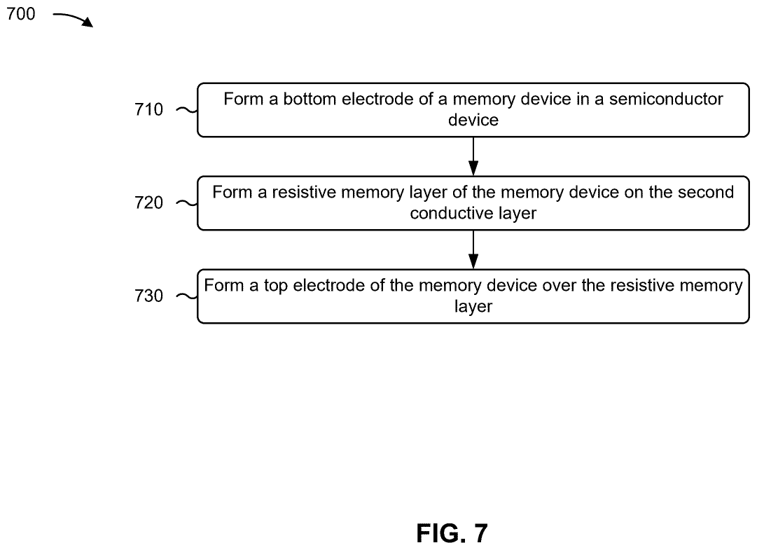

FIG. 7 is a flowchart of an example process 700 associated with forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a bottom electrode of a memory device in a semiconductor device (block 710). For example, one or more semiconductor processing tools may be used to form a bottom electrode (e.g., bottom electrode 136) of a memory device (e.g., memory device 126) in a semiconductor device (e.g., semiconductor device 100), as described herein. In some implementations, forming the bottom electrode includes depositing a first conductive layer (e.g., first conductive layer 136a), and forming a second conductive layer (e.g., second conductive layer 136b) on the first conductive layer, where the first conductive layer is a metal layer, and where the second conductive layer is a metal compound layer including a metal of the metal layer.

As further shown in FIG. 7, process 700 may include forming a resistive memory layer of the memory device on the second conductive layer (block 720). For example, one or more

semiconductor processing tools may be used to form a resistive memory layer (e.g., resistive memory layer 138) of the memory device on the second conductive layer, as described herein.

As further shown in FIG. 7, process 700 may include forming a top electrode of the memory device over the resistive memory layer (block 730). For example, one or more semiconductor processing tools may be used to form a top electrode (e.g., top electrode 140) of the memory device over the resistive memory layer, as described herein.

Process 700 may include additional implementations, such as any single implementation or any combination of implementations described below and/or in connection with one or more other processes described elsewhere herein.

In a first implementation, a work function of the metal compound layer is greater than a work function of the metal layer.

In a second implementation, alone or in combination with the first implementation, the metal of the metal layer is ruthenium (Ru), and the metal compound layer is a ruthenium oxide (RuOₓ) layer.

In a third implementation, alone or in combination with one or more of the first and second implementations, a work function of the metal compound layer is greater than a work function of ruthenium (Ru).

In a fourth implementation, alone or in combination with one or more of the first through third implementations, the second conductive layer is deposited or thermally formed on the first conductive layer.

In a fifth implementation, alone or in combination with one or more of the first through fourth implementations, the first conductive layer is deposited on a barrier layer (e.g., barrier layer 134).

In a sixth implementation, alone or in combination with one or more of the first through fifth implementations, a thickness of the second conductive layer is included in a range of approximately 50 angstroms to approximately 150 angstroms.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, an RRAM device includes a bottom electrode that includes a high work function material. The high work function material enables the work function of the bottom electrode to be tuned such that current leakage in the RRAM device is reduced in comparison to an RRAM device without the high work function material. For example, the high work function material provides a high electron barrier height at the interface between the bottom electrode and the resistive memory layer of the RRAM device, which more effectively resists current leakage through electron tunnelling than a lower work function material. As a result of the reduced current leakage, bias of an applied bitline voltage to set an RRAM device to the LRS is reduced or prevented, and the applied bitline voltage may correspond to a required set voltage, such that fewer voltage pulses will be required to achieve the LRS than when a low work function material is used for the bottom electrode. The reduced number of pulses needed to achieve the LRS increases memory device speed and increases overall device reliability.

As described in greater detail above, some implementations described herein provide a method. The method includes forming a bottom electrode of a memory device in a semiconductor device, where the bottom electrode is formed of an electrically conductive material including a metal oxide. The method includes forming a resistive memory layer of the memory device over the bottom electrode. The method includes forming a top electrode of the memory device over the resistive memory layer.

As described in greater detail above, some implementations described herein provide a memory device. The memory device includes a bottom electrode including a metal compound layer including a chemically inert metal that has a work function that is greater than a work function of ruthenium (Ru). The memory device includes a resistive memory layer on the bottom electrode, where the resistive memory layer includes a high dielectric constant (high-k) dielectric material. The memory device includes a top electrode on the resistive memory layer.

As described in greater detail above, some implementations described herein provide a method. The method includes forming a bottom electrode of a memory device in a semiconductor device, where forming the bottom electrode includes depositing a first conductive layer, and forming a second conductive layer on the first conductive layer, where the first conductive layer is a metal layer, and where the second conductive layer is a metal compound layer including a metal of the metal layer. The method includes forming a resistive memory layer of the memory device on the second conductive layer. The method includes forming a top electrode of the memory device over the resistive memory layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a bottom electrode of a memory device in a semiconductor device,
wherein the bottom electrode is formed of an electrically conductive material comprising a metal oxide;
forming a resistive memory layer of the memory device over the bottom electrode; and
forming a top electrode of the memory device over the resistive memory layer.

2. The method of claim 1, wherein the electrically conductive material is chemically inert.

3. The method of claim 1, wherein the electrically conductive material has a work function that is greater than a work function of ruthenium (Ru).

4. The method of claim 1, wherein the metal oxide comprises ruthenium oxide (RuOₓ).

5. The method of claim 4, wherein x in the RuOₓ is included in a range of approximately 1.5 to approximately 2.5.

6. The method of claim 1, wherein the bottom electrode comprises a bi-layer structure.

7. The method of claim 6, wherein the bi-layer structure comprises:
a first layer comprising a metal; and
a second layer comprising the metal oxide.

8. The method of claim 7, wherein the metal is ruthenium (Ru) and the metal oxide is ruthenium oxide (RuOₓ).

9. The method of claim 7, wherein the second layer is formed on the first layer; and
wherein the resistive memory layer is formed on the second layer.

10. A memory device, comprising:
a bottom electrode comprising a metal compound layer including a chemically inert metal that has a work function that is greater than a work function of ruthenium (Ru);
a resistive memory layer on the bottom electrode,
wherein the resistive memory layer comprises a high dielectric constant (high-k) dielectric material; and
a top electrode on the resistive memory layer.

11. The memory device of claim 10, wherein the bottom electrode further comprises a metal layer under the metal compound layer, and
wherein the metal compound layer is in contact with the resistive memory layer.

12. The memory device of claim 11, wherein the metal compound layer comprises an oxide, and
wherein the metal layer has a work function that is greater than the work function of ruthenium (Ru).

13. The memory device of claim 10, wherein a thickness of the bottom electrode is included in a range of approximately 50 angstroms to approximately 200 angstroms.

14. A method, comprising:
forming a bottom electrode of a memory device in a semiconductor device,
wherein forming the bottom electrode comprises:
depositing a first conductive layer;
forming a second conductive layer on the first conductive layer,
wherein the first conductive layer is a metal layer; and
wherein the second conductive layer is a metal compound layer comprising a metal of the metal layer;
forming a resistive memory layer of the memory device on the second conductive layer; and
forming a top electrode of the memory device over the resistive memory layer.

15. The method of claim 14, wherein a work function of the metal compound layer is greater than a work function of the metal layer.

16. The method of claim 14, wherein the metal of the metal layer is ruthenium (Ru); and
wherein the metal compound layer is a ruthenium oxide (RuOₓ) layer.

17. The method of claim 14, wherein a work function of the metal compound layer is greater than a work function of ruthenium (Ru).

18. The method of claim 14, wherein the second conductive layer is deposited or thermally formed on the first conductive layer.

19. The method of claim 14, wherein the first conductive layer is deposited on a barrier layer.

20. The method of claim 14, wherein a thickness of the second conductive layer is included in a range of approximately 50 angstroms to approximately 150 angstroms.
